(19) United States
(12) Patent Application Publication
(10) Pub. No.: US 2023/0369185 A1
(43) Pub. Date: Nov. 16, 2023

(54) SEMICONDUCTOR DEVICE

(71) Applicant: ROHM CO., LTD., Kyoto-shi, Kyoto (JP)

(72) Inventor: Yuto NISHIYAMA, Kyoto-shi, Kyoto (JP)

(21) Appl. No.: 18/246,172

(22) PCT Filed: Sep. 3, 2021
(86) PCT No.: PCT/JP2021/032447

§ 371 Date: Mar. 21, 2023

(30) Foreign Application Priority Data
Oct. 2, 2020 (JP) 2020-167588

(51) Int. Cl. H01L 23/495; H01L 23/31; H01L 23/00; H01L 25/16

(52) U.S. Cl. CPC H01L 23/49575; H01L 23/3121; H01L 24/49; H01L 23/49506; H01L 23/49513; H01L 24/48; H01L 23/49558; H01L 25/16; H01L 2224/49111; H01L 2224/49112; H01L 2224/48137; H01L 24/32; H01L 2224/06181; H01L 2224/0603; H01L 24/29; H01L 2924/13091; H01L 2224/32245; H01L 2224/32225; H01L 2224/48091; H01L 2224/48108; H01L 2224/48245; H01L 2224/73265; H01L 2224/29139; H01L 2924/10272; H01L 2224/06165; H01L 24/73

(57) ABSTRACT

A semiconductor device includes a switching element, a control element that controls the switching element, an island lead on which the switching element and the control element are mounted, and a plurality of terminal leads. The switching element includes a first electrode, a second electrode and a third electrode, where the first electrode and the second electrode are offset from the third electrode in a first sense of a thickness direction. The island lead has an obverse surface facing in the first sense of the thickness direction and supporting the switching element and the control element. Each terminal lead is electrically connected to the second electrode or the control element. The island lead is spaced apart from the plurality of terminal leads.

### TECHNICAL FIELD

The present disclosure relates to semiconductor devices.

### BACKGROUND ART

Patent document 1 discloses a semiconductor device including a MOSFET as a switching element. According to the document, the semiconductor device includes a plurality of leads for driving the switching element, with the leads protruding in one direction from a sealing resin.

### PRIOR ART DOCUMENT

### Patent Document

Patent Document 1: JP-A-2017-5165

### SUMMARY OF INVENTION

### Problem to be Solved by the Invention

A switching element designed for switching a higher voltage will cause a larger potential difference between the leads. It is therefore necessary to provide a greater distance between the leads, so that a semiconductor device having such a switching element tends to be large.

The present disclosure has been conceived in the circumstances described above and may aim, for example, to provide a semiconductor device that is usable for higher voltage and yet compact.

### Means to Solve the Problem

A semiconductor device according to the present disclosure includes a switching element, a control element that controls the switching element, an island lead on which the switching element and the control element are mounted, a plurality of terminal leads, and a resin member covering a portion of the island lead, a portion of each of the plurality of terminal leads, the switching element and the control element. The switching element includes a first electrode, a second electrode and a third electrode, where the first electrode and the second electrode are offset from the third electrode in a first sense of a thickness direction. The island lead has an obverse surface facing in the first sense of the thickness direction and a reverse surface facing in a second sense of the thickness direction, where the obverse surface supports the switching element and the control element. Each of the plurality of terminal leads is electrically connected to one of the second electrode or the control element. The island lead is spaced apart from the plurality of terminal leads.

### Advantages of Invention

The configuration described above can provide a semiconductor device that is usable for higher voltage and yet compact.

Other features and advantages of the present disclosure will be more apparent from the detailed description given below with reference to the accompanying drawings.

### BRIEF DESCRIPTION OF THE DRAWINGS

FIG. 1 is a plan view of a semiconductor device according to a first embodiment.

FIG. 2 is a fragmentary plan view of the semiconductor device according to the first embodiment.

FIG. 3 is a bottom view of the semiconductor device according to the first embodiment.

FIG. 4 is a front view of the semiconductor device according to the first embodiment.

FIG. 5 is a rear view of the semiconductor device according to the first embodiment.

FIG. 6 is a right-side view of the semiconductor device according to the first embodiment.

FIG. 7 is a sectional view taken along line VII-VII of FIG. 2.

FIG. 8 is a sectional view taken along line VIII-VIII of FIG. 2.

FIG. 9 is a sectional view taken along line IX-IX of FIG. 2.

FIG. 10 is a fragmentary plan view of a semiconductor device according to a second embodiment.

FIG. 11 is a sectional view taken along line XI-XI of FIG. 10.

FIG. 12 is a sectional view taken along line XII-XII of FIG. 10.

### MODE FOR CARRYING OUT THE INVENTION

The following describes preferred embodiments of the present disclosure with reference to the drawings.

In the present disclosure, the terms such as “first”, “second”, “third” and so on are used merely as labels and not intended to impose any ordinal or hierarchical limitations on the items modified by the terms.

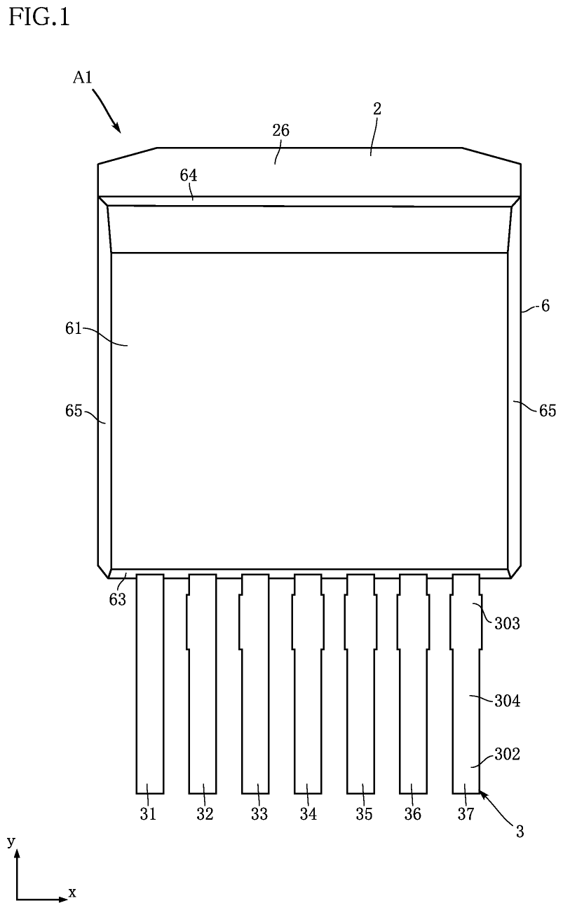

FIGS. 1 to 9 show a semiconductor device according to a first embodiment of the present disclosure. A semiconductor device A1 of this embodiment includes an island lead 2, a plurality of terminal leads 3, a switching element 4, a control element 5, an insulating layer 7, a resin member 6 and a plurality of wires 8. The semiconductor device A1 may be usable for various applications, such as power conversion, without being limited to a particular use. In one example, the semiconductor device A1 may be used as an AC/DC converter for industrial equipment. The AC/DC converter of the example may convert AC power of e.g. 1200 volts to DC power of e.g. 5 volts.

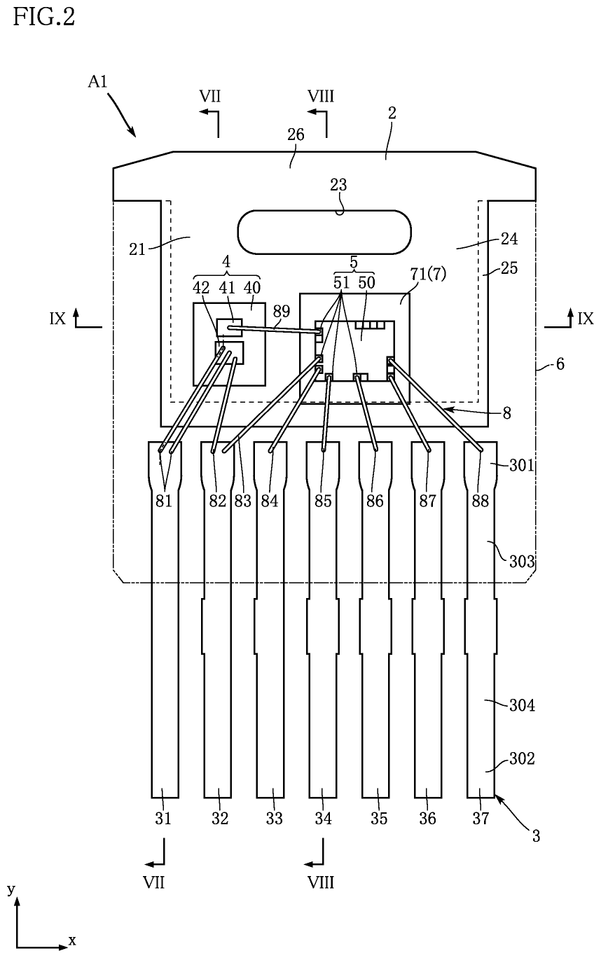

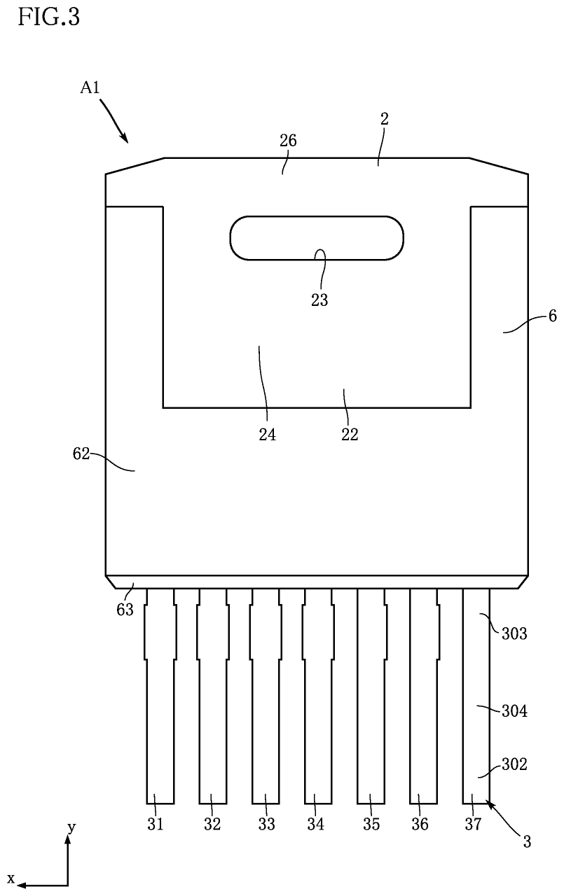

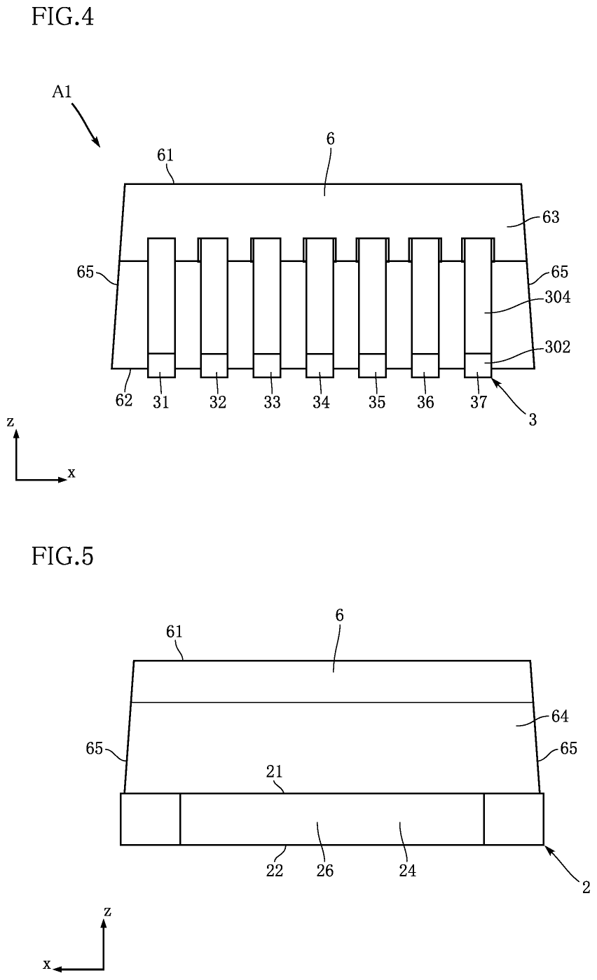

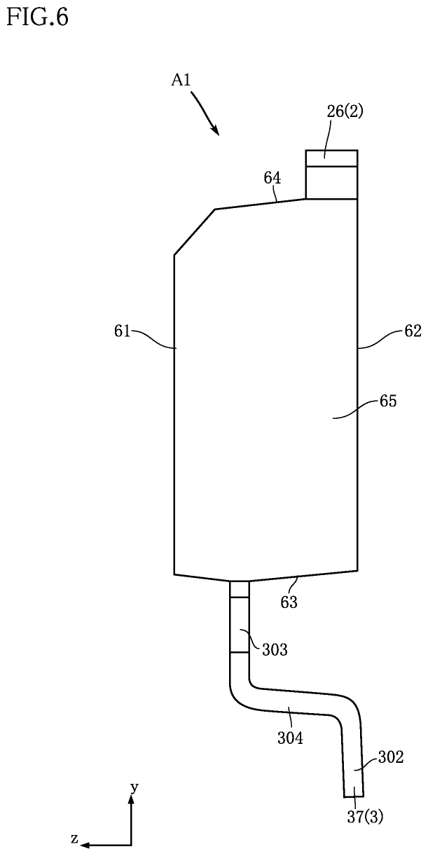

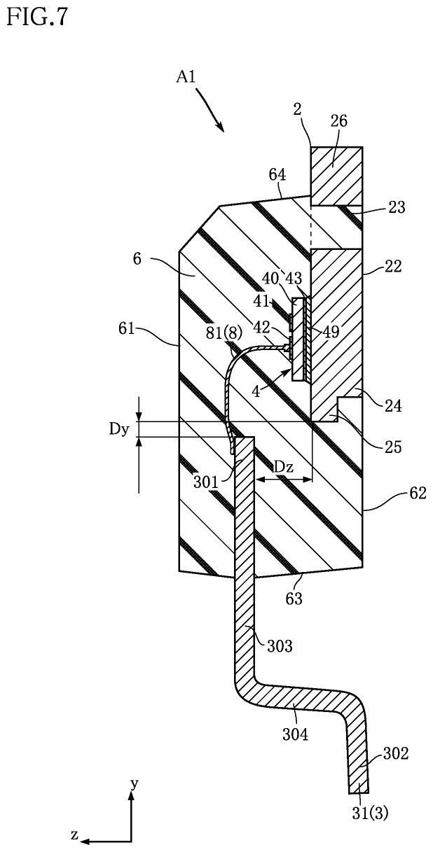

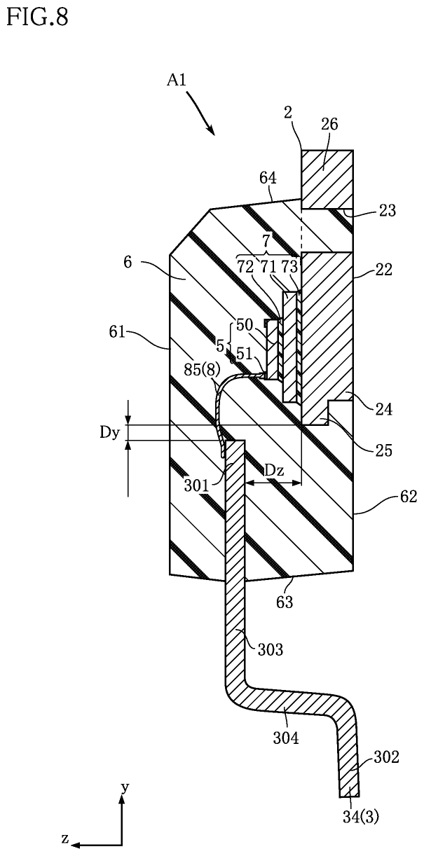

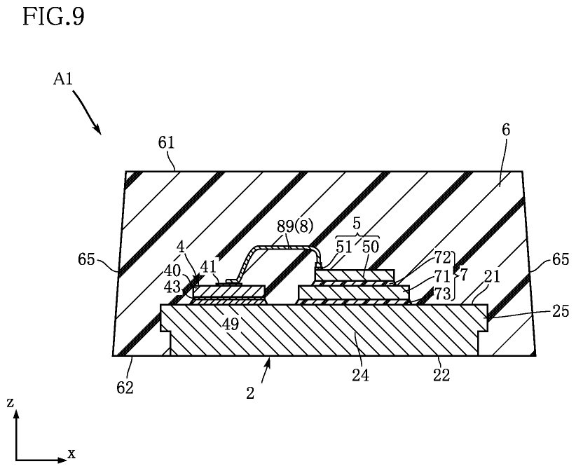

FIG. 1 is a plan view of the semiconductor device A1. FIG. 2 is a fragmentary plan view of the semiconductor device A1. FIG. 3 is a bottom view of the semiconductor device A1. FIG. 4 is a front view of the semiconductor device A1. FIG. 5 is a rear view of the semiconductor device A1. FIG. 6 is a right-side view of the semiconductor device A1. FIG. 7 is a sectional view taken along line VII-VII of FIG. 2. FIG. 8 is a sectional view taken along line VIII-VIII of FIG. 2. FIG. 9 is a sectional view taken along line IX-IX of FIG. 2. In these figures, the z direction is an example of the “thickness direction”, the x direction is an example of the “first direction”, and the y direction is an example of the “second direction”.

The island lead 2 supports the switching element 4 and the control element 5. The island lead 2 of this embodiment has an obverse surface 21, a reverse surface 22, a through-hole 23, a thick portion 24, a thin portion 25 and an protruding portion 26. The island lead 2 may be made of a conductive material, such as metal, but the material of the island lead 2 is not limited to such. In one example, the island lead 2 may be made of Cu, Fe, Ni or an alloy of such a metal. An appropriate portion of the island lead 2 may be plated with Ag, for example. In a different embodiment, the island lead 2 may be without one or more of the through-hole 23, the thick portion 24, the thin portion 25 or the protruding portion 26. The z-direction dimension of the island lead 2 (the thick portion 24) may be, but not limited to, about 0.9 to 1.5 mm for example, or about 1.3 mm, for example.

The obverse surface 21 faces in a first sense of the z direction (upward in FIG. 9). The reverse surface 22 faces in a second sense of the z direction (downward in FIG. 9) and is exposed from the resin member 6. When the semiconductor device A1 is mounted onto a circuit board or the like, the reverse surface 22 will be electrically connected to the circuit board. The thick portion 24 forms a portion of the obverse surface 21 and a portion of the reverse surface 22. In the illustrated example, the thick portion 24 is rectangular. The thin portion 25 extends from the thick portion 24 in a direction perpendicular to the z direction. The thin portion 25 forms a portion of the obverse surface 21 and has a smaller z-direction dimension than the thick portion 24. The thin portion 25 is offset from the reverse surface 22 in the first sense of the z direction and covered with the resin member 6 from the side in the second sense of the z direction.

The through-hole 23 extends throughout the thick portion 24 in the z direction. In the illustrated example, the through-hole 23 has a substantially oval or elliptical shape with the major axis extending in the x direction, but the shape of the through-hole 23 is not limited to such. The through-hole 23 is filled with a portion of the resin member 6. The protruding portion 26 extends in a first sense of the y direction (upward as viewed in FIG. 2) from the thick portion 24. The protruding portion 26 protrudes from the resin member 6 in the first sense of the y direction. In the illustrated example, the x-direction dimension of the protruding portion 26 is greater than the x-direction dimension of the thick portion 24.

Each terminal lead 3 is electrically connected to a second electrode 42 of the switching element 4 or to the control element 5 and spaced apart from the island lead 2. Any number of terminal leads 3 can be provided as necessary. The terminal leads 3 may be made of, but not limited to, a suitable conductive material, such as metal. Suitable materials for the terminal leads 3 include Cu, Fe, Ni and alloys of such metals. The terminal leads 3 may be provided with plating of, for example, Ag on appropriate portions. In this embodiment, the plurality of terminal leads 3 include seven terminal leads 31, 32, 33, 34, 35, 36 and 37. The terminal leads 31, 32, 33, 34, 35, 36 and 37 are arranged in the stated order from a side in a first sense of the x direction (left as viewed in FIG. 2) to a side in a second sense in the x direction (right as viewed in FIG. 2). In the illustrated example, the terminal leads 31, 32, 33, 34, 35, 36 and 37 are arranged at a substantially equal pitch but the pitch is not limited to such. Each of the terminal leads 3 (the terminal leads 31, 32, 33, 34, 35, 36 and 37) includes a bonding portion 301, a mounting portion 302, a first connecting portion 303 and a second connecting portion 304, forming as a whole a pin-like component with bends.

The bonding portion 301 is spaced apart from the island lead 2 in the second sense of the y direction (the downward direction as viewed in FIGS. 2, 7 and 8) and also in the first sense of the z direction (to the left as viewed in FIGS. 7 and 8). The bonding portion 301 is where a wire 8 is bonded. In the illustrated example, the bonding portion 301 is slightly greater in the x-direction dimension than the first connecting portion 303. Preferably, the bonding portion 301 is plated with, for example, Ag. In this embodiment, as shown in FIGS. 7 and 8, the distance between the island lead 2 (the obverse surface 21) and the bonding portion 301 in the z direction is denoted by Dz, and the distance between the island lead 2 (the thin portion 25) and the bonding portion 301 in the y direction is denoted by Dy, where the distance Dz is greater than the distance Dy. In the illustrated example, the bonding portion 301 is offset from the switching element 4 and the control element 5 in the first sense of the z direction. The z-direction dimension of the bonding portion 301 may be, but not limited to, about 0.5 mm, for example. The distance Dy may be about 0.5 mm, for example, which is less than the thickness of the island lead 2 (the thick portion 24). The distance Dz may be, but not limited to, about 1.3 mm, for example.

The mounting portion 302 extends in the second sense of the y direction to be exposed from the resin member 6. The mounting portion 302 has a position in the z direction that overlaps with the island lead 2 as viewed in the y direction. In the illustrated example, the mounting portion 302 is configured to have a surface facing in the second sense of the z direction that is substantially at the same level in the z direction as the obverse surface 21 of the island lead 2. When the semiconductor device A1 is mounted onto a circuit board or the like, the mounting portion 302 and the reverse surface 22 of the island lead 2 are attached and electrically connected to the circuit board. As such, the semiconductor device A1 is configure as a surface-mount device.

The first connecting portion 303 extends from the bonding portion 301 in the second sense of the y direction. The first connecting portion 303 includes a portion covered with the resin member 6 and a portion protruding from the resin member 6. The second connecting portion 304 connects the first connecting portion 303 and the mounting portion 302. The second connecting portion 304 extends in the z direction or in a direction slightly inclined relative to the z direction.

The switching element 4 is any suitable element for switching the input current. In this embodiment, the switching element 4 is a SiC-MOSFET, which is fabricated by using SiC as the main material of the semiconductor part. SiC-MOSFETs have an advantage of lower losses over, for example, Si-MOSFETs, which are fabricated by using Si as the main material of the semiconductor part. In this embodiment, the switching element 4 includes a semiconductor part 40, a first electrode 41, a second electrode 42 and a third electrode 43. In one example, the switching element 4 has an x-direction dimension of about 0.8 to 1.2 mm and a y-direction dimension of about 1.0 to 1.5 mm.

The switching element 4 is mounted on the obverse surface 21 of the island lead 2 at a location corresponding to the thick portion 24. In the illustrated example, the switching element 4 is located within the thick portion 24 closer to the end in the second sense of the y direction and also to the end in the first sense of the x direction. Also, the switching element 4 is offset from the through-hole 23 in the second sense of the y direction. The semiconductor part 40 is a semiconductor layer composed mainly of SiC. The first electrode 41 is located in the first sense of the z direction relative to the semiconductor part 40. The first electrode 41 is connected to the control element 5 by a wire 8. The second electrode 42 is located in the first sense of the z direction relative to the semiconductor part 40. The second electrode 42 is spaced apart from the first electrode 41 in the second sense of the y direction. The second electrode 42 is connected to the terminal leads 31 and 32 by a plurality of wires 8. The third electrode 43 is located in the second sense of the z direction relative to the semiconductor part 40. In this embodiment, the third electrode 43 is electrically connected to the obverse surface 21 of the island lead 2 at a location corresponding to the thick portion 24, via an electrically conductive bonding layer 49. The electrically conductive bonding layer 49 may be composed of solder or Ag paste, for example.

The control element 5 is an integrated circuit element for controlling the switching operation of the switching element 4. The control element 5 includes an element body 50 and a plurality of electrode pads 51. The element body 50 is a part forming an integrated circuit and rectangular as viewed in the z direction. The electrode pads 51 are disposed along the four edges of the element body 50. In one example, the control element 5 has an x-direction dimension of about 1.2 to 1.6 mm and a y-direction dimension of about 0.8 to 1.2 mm.

The control element 5 is supported on the obverse surface 21 of the island lead 2 at a location corresponding to the thick portion 24. The control element 5 is spaced apart from the switching element 4 in a second sense of the X direction. The switching element 4 and the control element 5 are located to overlap with each other as viewed in the x direction. The control element 5 may be mounted by using any suitable mounting technique.

In this embodiment, the insulating layer 7 is disposed between the control element 5 and the obverse surface 21 of the island lead 2. The insulating layer 7 is for providing appropriate insulation between the control element 5 and a die-bonding portion 11, which is held at the same potential as the third electrode 43 of the switching element 4. In this embodiment, the insulating layer 7 includes a solid layer 71 and bonding layers 72 and 73 as shown in FIGS. 8 and 9, but the insulating layer 7 is not limited to such a configuration.

The solid layer 71 is made of a material having suitable insulating properties. For example, insulating materials, including ceramic materials, such as alumina, and Si may be used. The bonding layer 72 bonds the control element 5 and the solid layer 71. The bonding layer 73 bonds the solid layer 71 and the obverse surface 21 of the island lead 2. In this embodiment, the bonding layers 72 and 73 are made of an insulating bonding material, but the bonding layers 72 and 73 are not limited to such. As shown in FIG. 2, the insulating layer 7 of this embodiment is larger than the control element 5 as viewed in the z direction, extending beyond the opposite ends of the control element 5 in the x and y directions.

The resin member 6 covers a portion of the island lead 2, a portion of each terminal lead 3, the switching element 4, the control element 5, the insulating layer 7 and the wires 8. The resin member 6 may be made of, but not limited to, a black epoxy resin mixed with fillers. The z-direction dimension of the resin member 6 may be, but not to, about 4.0 to 5.0 mm, for example, or about 4.4 mm, for example.

As shown in FIGS. 1 to 9, the resin member 6 has a resin obverse surface 61, a resin reverse surface 62, a resin end surface 63, a resin end surface 64 and a pair of resin side surfaces 65.

The resin obverse surface 61 faces in the first sense of the z direction. In this embodiment, the resin obverse surface 61 is perpendicular to the z direction and substantially rectangular as viewed in the z direction. The resin reverse surface 62 faces in the second sense of the z direction. In this embodiment, the resin reverse surface 62 is perpendicular to the z direction. In this embodiment, the resin reverse surface 62 is exposed on the reverse surface 22 of the island lead 2.

The resin end surface 63 is located in the second sense of the y direction. In the illustrated example, the resin end surface 63 is composed of a plurality of regions slightly inclined relative to the z direction. In this embodiment, the terminal leads 3 (the first connecting portions 303) protrude from the resin end surface 63. The resin end surface 64 is located in the first sense of the y direction. In the illustrated example, the resin end surface 64 is composed of a plurality of regions slightly inclined relative to the z direction and a region parallel to the z direction. In this embodiment, the protruding portion 26 of the island lead 2 protrudes from the resin end surface 64.

The pair of resin side surfaces 65 are opposed to each other in the x direction. In the illustrated example, each resin side surface 65 is a flat plane slightly inclined relative to the z direction.

The resin member 6 of this embodiment has a portion filling the through-hole 23. The resin reverse surface 62 is substantially flush with the reverse surface 22 of the island lead 2. The resin member 6 covers the thin portion 25 of the island lead 2 from the side in the second sense of the z direction.

The plurality of wires 8 are used to connect the terminal leads 3, the switching element 4, and the control element 5 as necessary. The wires 8 may be threads of metal such as Au, Al or Cu but the material of the wires 8 is not limited to such. As shown in FIG. 2, the plurality of wires 8 of this embodiment include first wires 81 and 82, second wires 83, 84, 85, 86, 87 and 88, and a third wire 89. The first wires 81 and 82, the second wires 83, 84, 85, 86, 87 and 88, and the third wire 89 are of the type formed by using a capillary tool.

The first wire 81 connects the second electrode 42 of the switching element 4 and the bonding portion 301 of the terminal lead 31. In this embodiment, two first wires 81 are provided. Note that any number of first wire 81 may be provided, including one or three or more. The current to be switched is passed through the second electrode 42, and a plurality of first wires 81 are desirable for reducing the resistance to the current. As shown in FIG. 7, each first wire 81 includes a first bonding portion connected to the second electrode 42 and a second bonding portion connected to the bonding portion 301.

The first wire 82 connects the second electrode 42 of the switching element 4 and the bonding portion 301 of the terminal lead 32. The first wire 82 includes a first bonding portion connected to the second electrode 42 and a second bonding portion connected to the bonding portion 301.

The second wire 83 connects an electrode pad 51 of the control element 5 and the bonding portion 301 of the terminal lead 32. The second wire 83 includes a first bonding portion connected to the electrode pad 51 and a second bonding portion connected to the bonding portion 301.

The second wire 84 connects an electrode pad 51 of the control element 5 and the bonding portion 301 of the terminal lead 33. The second wire 84 includes a first bonding portion connected to the electrode pad 51 and a second bonding portion connected to the bonding portion 301.

The second wire 85 connects an electrode pad 51 of the control element 5 and the bonding portion 301 of the terminal lead 34. The second wire 85 includes a first bonding portion connected to the electrode pad 51 and a second bonding portion connected to the bonding portion 301.

The second wire 86 connects an electrode pad 51 of the control element 5 and the bonding portion 301 of the terminal lead 35. The second wire 86 includes a first bonding portion connected to the electrode pad 51 and a second bonding portion connected to the bonding portion 301.

The second wire 87 connects an electrode pad 51 of the control element 5 and the bonding portion 301 of the terminal lead 36. The second wire 87 includes a first bonding portion connected to the electrode pad 51 and a second bonding portion connected to the bonding portion 301.

The second wire 88 connects an electrode pad 51 of the control element 5 and the bonding portion 301 of the terminal lead 37. The second wire 88 includes a first bonding portion connected to the electrode pad 51 and a second bonding portion connected to the bonding portion 301.

The third wire 89 connects the first electrode 41 of the switching element 4 and an electrode pad 51 of the control element 5. The third wire 89 includes a first bonding portion connected to the electrode pad 51 and a second bonding portion connected to the first electrode 41.

The following describes advantages of the semiconductor device A1.

According to this embodiment, the third electrode 43 of the switching element 4 is electrically bonded to the island lead 2. The island lead 2 and the plurality of terminal leads 31 are spaced apart from each other. This provides more reliable insulation between the island lead 2 and the terminal leads 3 when a high voltage of the order of 1700 V is applied to the island lead 2. In addition, the potential difference between the terminal leads 3 is significantly small relative to the potential difference between each terminal lead 3 and the island lead 2. Consequently, it is not necessary to excessively increase the distance between the adjacent terminal leads 3 (the pitch in the x direction shown in FIG. 2). The semiconductor device A1 can therefore be configured to be usable for higher voltage and yet compact.

The control element 5 is insulated from the island lead 2 by the insulating layer 7. This ensures proper operation of the control element 5 regardless of the voltage applied to the island lead 2.

The reverse surface 22 of the island lead 2 is exposed on the resin reverse surface 62 of the resin member 6. With this configuration, the area of the reverse surface 22 is allowed to be larger than, for example, the area of the mounting portion 302 of each terminal lead 3. This is desirable for reducing the resistance and for dissipating the heat from the switching element 4.

The switching element 4 and the control element 5 are adjacent in the x direction with a suitable space therebetween. This arrangement can prevent the distance from the bonding portion 301 of any terminal lead 3 to one of the switching element 4 and the control element 5 from being unduly long.

As shown in FIGS. 7 and 8, the distance Dz between the bonding portion 301 and the obverse surface 21 of the island lead 2 in the z direction is greater than the distance Dy between the bonding portion 301 and the island lead 2 (the thin portion 25). As such, a greater distance can be provided between the island lead 2 and the bonding portion 301 without requiring the bonding portion 301 to be excessively remote from the island lead 2 in the y direction. This facilitates the reduction of the y-direction dimension of the semiconductor device A1.

The mounting portions 302 of the terminal leads 3 and the reverse surface 22 are located at substantially the same position in the z direction and thus usable for surface mounting of the semiconductor device A1.

The island lead 2 having the through-hole 23 and the thin portion 25 is desirable for preventing unintentional detachment of the island lead 2 from the resin member 6.

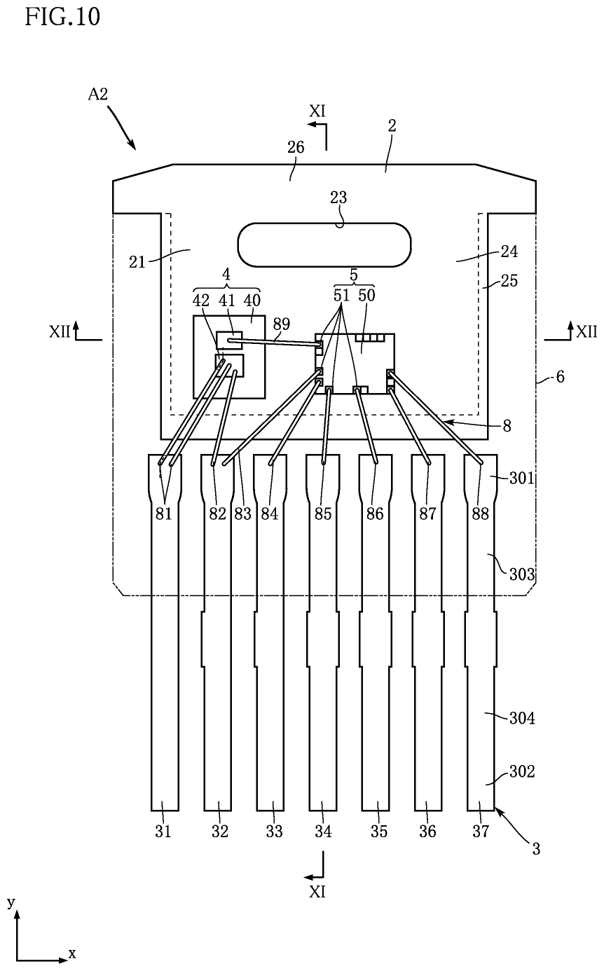

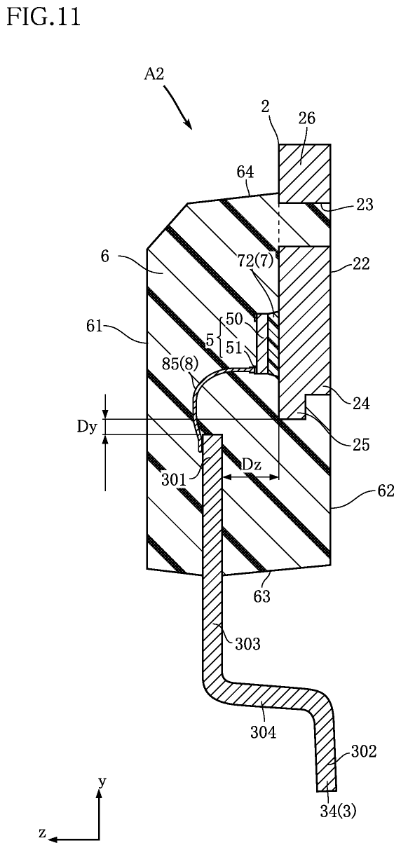

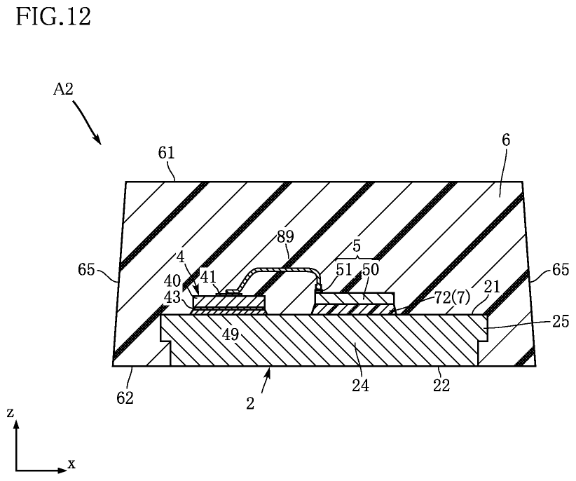

FIGS. 10 to 12 show another embodiment of the present disclosure. In these figures, elements identical or similar to those of the embodiment described above are given the same reference numerals as those of the above embodiment.

FIGS. 10 to 12 illustrate a semiconductor device according to a second embodiment. A semiconductor device A2 of this embodiment includes an insulating layer 7 of a different configuration from that of the embodiment described above.

The insulating layer 7 of this embodiment is composed solely of a bonding layer 72. The bonding layer 72 is made of an insulating bonding material, as in the embodiment described above. Preferably, the insulating layer 7 of this embodiment is thicker than the insulating layer 7 of the semiconductor device A1 but the thickness (the z-direction dimension) thereof is not specifically limited.

The semiconductor device A2 according to this embodiment can therefore be configured to be usable for higher voltage and yet compact. Moreover, the insulating layer 7 does not extend much beyond the edges of the control element 5. This configuration is desirable for reducing the size of the semiconductor device A2 as viewed in the z direction.

The semiconductor device according to the present disclosure is not limited to the embodiments described above. Various design changes can be made to the specific configuration of each part of the semiconductor device according to the present disclosure. The configurations described in the following clauses are included in embodiments of the present disclosure.

Clause 1.

A semiconductor device comprising:
a switching element;
a control element that controls the switching element;
an island lead on which the switching element and the control element are mounted;
a plurality of terminal leads; and
a resin member covering a portion of the island lead, a portion of each of the plurality of terminal leads, the switching element and the control element, wherein
the switching element includes a first electrode, a second electrode and a third electrode, the first electrode and the second electrode being offset from the third electrode in a first sense of a thickness direction,
the island lead has an obverse surface facing in the first sense of the thickness direction and a reverse surface facing in a second sense of the thickness direction, the obverse surface supporting the switching element and the control element,
each of the plurality of terminal leads is electrically connected to one of the second electrode or the control element, and
the island lead is spaced apart from the plurality of terminal leads.

Clause 2.

The semiconductor device according to Clause 1, wherein the third electrode is electrically bonded to the obverse surface of the island lead.

Clause 3.

The semiconductor device according to Clause 2, further comprising an insulating layer interposed between the control element and the obverse surface of the island lead.

Clause 4.

The semiconductor device according to Clause 3, wherein the reverse surface of the island lead is exposed from the resin member.

Clause 5.

The semiconductor device according to Clause 4, wherein the switching element and the control element are spaced apart from each other in a first direction perpendicular to the thickness direction.

Clause 6.

The semiconductor device according to Clause 5, wherein the plurality of terminal leads protrude from the resin member in a second direction that is perpendicular to the thickness direction and the first direction.

Clause 7.

The semiconductor device according to Clause 6, wherein the island lead is spaced apart from the plurality of terminal leads in the second direction as viewed in the thickness direction.

Clause 8.

The semiconductor device according to Clause 7, wherein the plurality of terminal leads include a bonding portion covered by the resin member and offset from the island lead in the first sense of the thickness direction.

Clause 9.

The semiconductor device according to Clause 8, wherein a distance between the bonding portion and the island lead in the thickness direction is greater than a distance between the bonding portion and the island lead in the second direction.

Clause 10.

The semiconductor device according to Clause 8 or 9, wherein the plurality of terminal leads include a mounting portion exposed from the resin member, the mounting portion having a position in the thickness direction that overlaps with the island lead as viewed in the second direction.

Clause 11.

The semiconductor device according to Clause 10, wherein the plurality of terminal leads are arranged at an equal pitch in the first direction.

Clause 12.

The semiconductor device according to any one of Clauses 8 to 11, further comprising a first wire connected to the second electrode and one of the bonding portions of the plurality of terminal leads.

Clause 13.

The semiconductor device according to Clause 12, further comprising a second wire connected to the control element and one of the bonding portions of the plurality of terminal leads.

Clause 14.

The semiconductor device according to Clause 13, further comprising a third wire connected to the first electrode and the control element.

Clause 15.

The semiconductor device according to any one of Clauses 1 to 14, wherein the island lead has a through-hole extending in the thickness direction, and the through-hole is filled with a portion of the resin member.

Clause 16.

The semiconductor device according to any one of Clauses 1 to 15, wherein the switching element includes a semiconductor part composed mainly of SiC.

Clause 17.

The semiconductor device according to any one of Clauses 1 to 16, wherein the first electrode comprises a gate electrode, the second electrode comprises a source electrode, and the third electrode comprises a drain electrode.

### REFERENCE NUMERALS

| | |
|---|---|
| A1, A2: Semiconductor device | 2: Island lead |
| 3: Terminal lead | 4: Switching element |
| 5: Control element | 6: Resin member |
| 7: Insulating layer | 8: Wire |
| 11: Die-bonding portion | 21: Obverse surface |
| 22: Reverse surface | 23: Through-hole |
| 24: Thick portion | 25: Thin portion |
| 26: Protruding portion | |
| 31, 32, 33, 34, 35, 36, 37: Terminal lead | |
| 40: Semiconductor part | 41: First electrode |
| 42: Second electrode | 43: Third electrode |
| 49: Electrically conductive bonding layer | 50: Element body |
| 51: Electrode pad | 61: Resin obverse surface |
| 62: Resin reverse surface | 63: Resin end surface |
| 64: Resin end surface | 65: Resin side surface |
| 71: Solid layer | 72, 73: Bonding layer |
| 81, 82: First wire | |
| 83, 84, 85, 86, 87, 88: Second wire | |
| 89: Third wire | 301: Bonding portion |
| 302: Mounting portion | 303: First connecting portion |
| 304: Second connecting portion | Dy, Dz: Distance |

1. A semiconductor device comprising:
a switching element;
a control element that controls the switching element;
an island lead on which the switching element and the control element are mounted;
a plurality of terminal leads; and
a resin member covering a portion of the island lead, a portion of each of the plurality of terminal leads, the switching element and the control element, wherein
the switching element includes a first electrode, a second electrode and a third electrode, the first electrode and the second electrode being offset from the third electrode in a first sense of a thickness direction,
the island lead has an obverse surface facing in the first sense of the thickness direction and a reverse surface facing in a second sense of the thickness direction, the obverse surface supporting the switching element and the control element,
each of the plurality of terminal leads is electrically connected to one of the second electrode or the control element, and
the island lead is spaced apart from the plurality of terminal leads.

2. The semiconductor device according to claim 1, wherein the third electrode is electrically bonded to the obverse surface of the island lead.

3. The semiconductor device according to claim 2, further comprising an insulating layer interposed between the control element and the obverse surface of the island lead.

4. The semiconductor device according to claim 3, wherein the reverse surface of the island lead is exposed from the resin member.

5. The semiconductor device according to claim 4, wherein the switching element and the control element are spaced apart from each other in a first direction perpendicular to the thickness direction.

6. The semiconductor device according to claim 5, wherein the plurality of terminal leads protrude from the resin member in a second direction that is perpendicular to the thickness direction and the first direction.

7. The semiconductor device according to claim 6, wherein the island lead is spaced apart from the plurality of terminal leads in the second direction as viewed in the thickness direction.

8. The semiconductor device according to claim 7, wherein the plurality of terminal leads include a bonding portion covered by the resin member and offset from the island lead in the first sense of the thickness direction.

9. The semiconductor device according to claim 8, wherein a distance between the bonding portion and the island lead in the thickness direction is greater than a distance between the bonding portion and the island lead in the second direction.

10. The semiconductor device according to claim 8, wherein the plurality of terminal leads include a mounting portion exposed from the resin member, the mounting portion having a position in the thickness direction that overlaps with the island lead as viewed in the second direction.

11. The semiconductor device according to claim 10, wherein the plurality of terminal leads are arranged at an equal pitch in the first direction.

12. The semiconductor device according to claim 8, further comprising a first wire connected to the second electrode and one of the bonding portions of the plurality of terminal leads.

13. The semiconductor device according to claim 12, further comprising a second wire connected to the control element and one of the bonding portions of the plurality of terminal leads.

14. The semiconductor device according to claim 13, further comprising a third wire connected to the first electrode and the control element.

15. The semiconductor device according to claim 1, wherein the island lead has a through-hole extending in the thickness direction, and
the through-hole is filled with a portion of the resin member.

16. The semiconductor device according to claim 1, wherein the switching element includes a semiconductor part composed mainly of SiC.

17. The semiconductor device according to claim 1, wherein the first electrode comprises a gate electrode, the second electrode comprises a source electrode, and the third electrode comprises a drain electrode.
